(19) United States
(12) Patent Application Publication
(10) Pub. No.: US 2013/0127430 A1
(43) Pub. Date: May 23, 2013

(54) Power Regulator for Driving Pulse Width Modulator

(71) Applicant: Diodes Incorporated, Plano, TX (US)

(72) Inventor: Frederick KwokYin Leung, Cupertino, CA (US)

(73) Assignee: Diodes Incorporated, Plano, TX (US)

(21) Appl. No.: 13/668,933

(22) Filed: Nov. 5, 2012

Related U.S. Application Data
(60) Provisional application No. 61/561,731, filed on Nov. 18, 2011.

(51) Int. Cl. G05F 1/10; H03K 5/24

(52) U.S. Cl. 323/282; 327/77

(57) ABSTRACT

A voltage regulator that modulates the switching of a switching circuit to regulate the output voltage level supplied to a system. The regulator uses a comparator circuit to compare a reference signal to an analog signal derived from the output voltage of the regulator, and outputs a binary signal based on the comparison. The regulator may use a counter circuit that interrogates the binary signal from the comparator circuit and generates a counter signal proportional to, for example, the duration of the binary signal when it stays in one of the two binary states. The regulator then uses a trigger circuit that generates a signal based on the counter signal to effectuate the modulation of the switching of the switching circuit. The reference signal may be modified by a hysteresis level adjuster to force a triggering event at the switching circuit.

### BACKGROUND OF THE INVENTION

The present invention relates to power electronics and specifically relates to a class of electronic power supplies whose output is regulated with pulse width modulation.

The broad area of power electronics deals with processing and control of electric power in applications ranging from on-chip power management at milli-watt level to power converters for motor drives or power system utility at hundreds of megawatts. Common to these diverse applications is the requirement of efficient regulation of inputs and outputs under a range of operating conditions with minimum loss of power. In order to achieve this goal, a well regulated power conversion system is necessary.

Switching power converter is an essential component of many of the power conversion systems. The converters usually include integrated circuits, power semiconductor devices as well as passive (capacitive and inductive) components, and the control of the power semiconductor devices is an integral part of power converter regulation.

Power semiconductor devices in switched mode power supplies operate at hundreds of kilohertz to megahertz. As a consequence signal processing at even higher frequency would be required to implement digital control to match in dynamic performance of standard analog solutions. It is common practice in applications such as motor drives and power converters for utility interfaces to use advance digital control methods and digital controllers. And many such controllers are based on general purpose or dedicated microprocessors or digital signal processors (DSP). These digital controls, some operate at hundreds of megahertz or higher, have reduced the size and weight of energy storage passive components, and enables fast dynamic regulation.

In order to take full advantage of the dedicated microprocessors and the digital signal processors that support the controllers, practitioners often use signal buses extensively in switching power converters. For instance, a feedback signal, which may be a fraction of the output voltage and is used to modulate the switching pulses switching the power devices, is often converted with an analog to digital converter immediately following a voltage divider from an analog form to digital form. Depending on the type of microprocessor, digital signal processor, or interface of the controller, the digital representation of the feedback signal may be 8, 10 bits or wider. And because the feedback signal is on a critical control path, the signal speed is of the essence to, for example, the power control and management system, the digital compensation and control system.

### SUMMARY OF THE INVENTION

Applicants recognize that the width and the speed of the feedback signal necessitate similar requirement to, for example, the power control and management system, the digital compensation and control system. Such a power conversion system suffers on costly components and high power consumption. With this recognition, Applicants invented apparatuses and methods that meliorate the problems of digital power controller in the art and maintain its advantages over traditional analog controllers.

In one aspect of the invention, the controller converts the feedback signal to a single-bit instead of multi-bit binary signal. The conveyance and manipulation of this single-bit signal according to this invention result in a controller having superior functionalities of the controller without the burden of excessive hardware overhead and the power consumption associated therewith.

In one exemplary embodiment, the feedback signal in its original analog form is compared to a reference signal in a comparator. The output of this comparator is binary form and is fed to a high frequency counter. As a result, information carried on the feedback signal is embedded in the output signal of the counter. The output signal is high frequency and therefore is capable of high resolution representation of this information latent signal and can be used in many applications as will be detailed in a later section of this application.

Contrarily, in another aspect of this invention, in some applications, the binary feedback signal may be interrogated as is without having to pass through a high-speed counter. It can be so when high resolution of this signal is not necessary for the function the applications.

For clarity, in this paper, an Analog-to-Digital Converter (ADC) is defined as a circuit that converts an analog signal into a multi-bit binary signal that represents the value of the analog signal in digital form. A comparator is a circuit that compares two signals and outputs a single-bit binary signal represents the relative amplitude of the two signals.

### BRIEF DESCRIPTION OF THE DRAWINGS

FIG. 1 depicts a portion of a power regulator, which includes a digital counter.

FIG. 2 depicts a portion of a power regulator, which includes a digital counter, a lookup table, and a pulse width modulator.

FIG. 3 depicts a portion of a digital power regulator, which includes a hysteresis level adjuster.

### DETAILED DESCRIPTION OF EXEMPLARY EMBODIMENTS

### Example 1

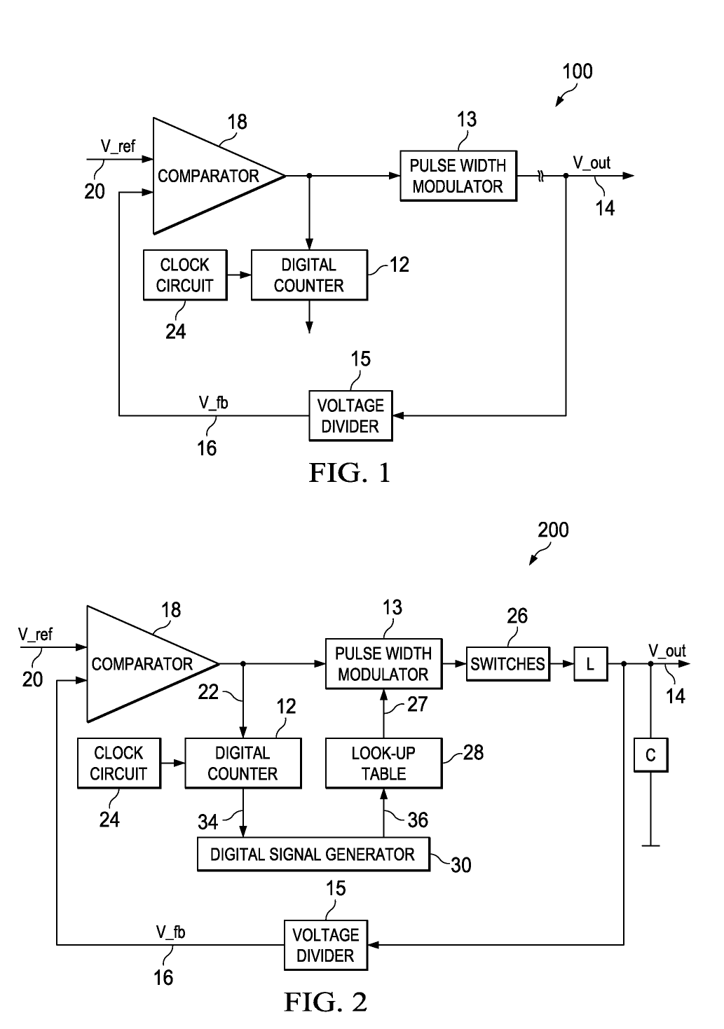

FIG. 1 depicts a portion of an exemplary power controller 100, which includes a digital counter 12. Similar to controllers in the known art, the function of this power controller is to maintain the output voltage V_out 14 at a desired voltage range under various loading conditions by feeding back a fraction of the output voltage V_out 14 to be interrogated within the controller. The inventive controller 100 makes the interrogation speedy and without consumes excessive power in doing so.

As depicted in FIG. 1, a feedback signal V_fb 16, which is a fraction of the output voltage V_out 14 is generated with a voltage divider 15 and is fed into a comparator 18 at one input terminal. The other terminal of the comparator connects to a reference voltage V_ref 20. In this example, V_ref 20 may have a value set at a fraction of a voltage at which the output voltage V_out 14 is aspired to maintain.

The result of the comparison between V_fb 16 and V_ref 20 at the comparator 18 is manifested at the output of the comparator 18 in the form of a onebit binary signal 22. For example, the comparator may output a zero when V_ref 20 is higher than V_fb 16 and outputs a one when V_ref 20 is lower than V_fb 16. If V_fb 16 has a sine wave shape, the one-bit binary signal may become a zero when V_fb 16 is near the peak of the sine wave, and changes to a one when V_fb 16 is near the valley of the wave.

V_ref 20 may be held as a constant voltage, or it may be a variable voltage. In some occasions, V_ref 20 may be a constant voltage modulated into a signal with a sawtooth wave form.

In this exemplary embodiment, the one-bit binary signal 22 is fed into a pulse width modulator 13 and a digital counter 12. This digital counter 12 runs on a clock that may be ten times faster than the switching speed of the power switches. In one exemplary embodiment, the switching frequency is in the range of 64 KHz and the counter clock frequency is around 64 MHz.

Because of the counter is running at a high frequency, it can be constructed and programmed to measure the one-bit signal 22 in minute steps. For example, it can accurately record the time when the one-bit signal 22 switches from one binary state to the other binary state; and it can accurately record the duration in which the one-bit signal 22 stays at one or the other binary state.

With this exemplary embodiment, a person skilled in the art of power controller can easily see that even though the feedback signal is kept in its original analog form when it is fed into the comparator, the combination of the comparator 18 and the digital counter 12 can capture the information embedded in the feedback signal speedily and with high accuracy. Some of the applications of this information are described below.

### Example 2

FIG. 2 depicts a portion of a power controller 200, which includes a digital counter 12, a look-up table 28, and a pulse width modulator circuit 13. The controller controls the switching of the switches in a switching circuit 26 without having to use an analog-to-digital converter to convert the analog feedback signal V_fb 16 to a digital signal.

In this controller, the feedback signal V_fb 16 is generated with a voltage divider 15, which fractions the output voltage V_out 14 down to a level comparable to a reference voltage V_ref 20. The feedback signal 16 is then fed into a comparator 18 and compared to the reference voltage V_ref 20.

The comparator 18 generates, based on the comparison, a one-bit binary signal 22, which is then fed into a digital counter 12 and into a pulse width modulator 13. The digital counter runs at a frequency of a high-speed clock 24. The clocking frequency is usually higher than the frequency at which the switches in the switching circuit 26 operate.

In this exemplary controller, the digital counter 12 receives the binary signal 22 from the comparator 18 and interrogates it at the clock 24 frequency. The clock frequency limits the resolution of the interrogating. In one instance, it measures the duration of the binary signal 22 when it stays in one of the two binary states. For example, it may count in number of clock cycles during which the feedback signal V_fb 16 has a value that is lower than that of the reference voltage V_ref 20. The counter may otherwise counts the duration of which the feedback signal V_fb 16 has a value that is higher than that of the reference voltage V_ref 20. And the counter may be so constructed and programmed to reset the count when the feedback signal V_fb 16 crosses the reference voltage V_ref 20, at which time the polarity of the binary signal flips. The result of the count is represented as a count signal 34 accessible from the counter.

This exemplary controller also contains a delta generator 30, which receives the count signal 34 and generates a delta signal 36 representing the difference between the count signal 34 and a target value. The target value, for instance, may be represent a preset duty cycle of pulses that operates the switching circuit 26. And the delta signal 36 may indicate the presence of variation in the supply voltage or a change in the loading condition, which cause the output voltage to deviate from the desired value.

The delta signal 36 directs the pulse width modulator 32 to modify the pulses from the modulator, including the period of the pulses and the duty cycle of the pulses. In this paper, a period of a pulse is the time spanning from a rising edge of a pulse to the rising edge of the following pulse; the duty cycle of a pulse is the ratio of duration within one period when the pulse is on to the duration when it is off.

The delta signal 36 may be directly fed to the pulse width modulator circuit 32. Alternatively, it may be fed to a look-up table 28. The look-up table 28 may contain a set of predetermined number selectably arranged, or it may contain a combination logic circuit representing a linear or a nonlinear formula that produces a signal value corresponding to the delta signal 36. The selected value or the generated value is then embedded in a look-up signal 27 accessible to the pulse width modulator circuit 32 and which in turn controls the timing and the duration of switches in the switching circuit 26.

In this embodiment, the switching circuit, which contains one or more switches in the form of power MOSFETs, may or may not be built in a semiconductor chip as the controller. If the switches are integrated with the pulse width modulator, the chip may be referred to as a single chip power regulator; and if, on the other hand, the switches and the controller are built on separate semiconductor chips, the chips can still be assembled in an integrated package that function as a full power regulator.

### Example 3

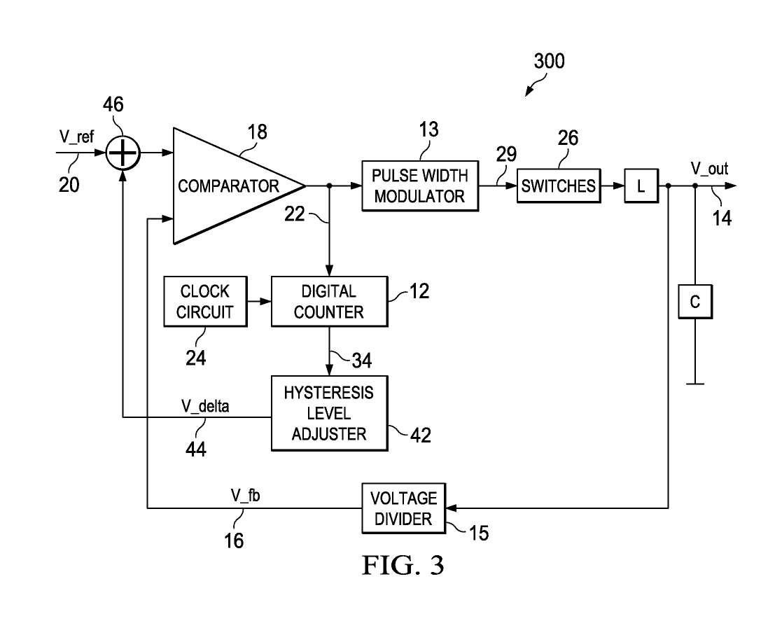

FIG. 3 depicts a portion of a power controller 300, which includes a hysteresis level adjuster 42 and a hysteresis level adder 46, in addition to a digital counter 12. This controller is constructed to maintain the frequency of the pulse 29 that triggers the switching circuits 26 at a stable level when the ripple component of from the feedback signal V_fb 16 is too weak to cause proper triggering in the comparator.

In this exemplary controller, the feedback voltage V_fb 16 can be regarded as a dc or a very slow varying signal incorporated with a ripple component. The ripple component of the feedback voltage is the result of the capacitive component or components associated with the switching circuit.

At the comparator 18, the ripple portion of the feedback signal is designed to be “detected” by the comparator and hence triggers a flip of binary signal 22 at its output. In anticipation of “catching” the ripple signal at its peaks and the valleys, the comparator is 18 is usually designed that splits the reference voltage into a high voltage limit and a low voltage limit. The splitting of the reference voltage is for the purpose that unintended noise associated with the V_fb 16 would not false-trigger the comparator. This separation of the V_ref 20 is referred in the art as the hysteresis of the comparator. In some comparators, the hysteresis may be an inherent characteristic; or it may also be a design feature in other comparators.

With a given hysteresis, there may be occasions when the ripple component of the feedback signal V_fb 16 is too weak such that the comparator fails to detect the peaks or the valleys of the ripple, or both. When this happens, the controller will miss a trigger pulse or pulses. As a consequence, the switching frequency may deviate from the desired range.

Known remedies to this problem include generating of a separate and artificial ripple of sufficient magnitude to force detection. One such method is described in U.S. Pat. No. 7,202,642 titled Switching Regulator Capable of Raising System Stability by Virtual Ripple.

A superior alternative solution is depicted in FIG. 3. This controller depicted in FIG. 3 is constructed to shift the hysteresis level as when necessary so that even weak ripple can be properly detected.

In this exemplary controller, the feedback voltage signal V_fb 16 and a reference signal V_ref 20, similar to that as explained in Example 1 and Example 2 above, are fed to the comparator 18. The binary signal 22 as the result of the comparison is fed to the counter 12, which interrogates it at the frequency of a high-speed clock 24.

The result of the interrogation at the counter 12 is embedded in the count signal 34, which is then fed into a hysteresis level adjuster 42 where it is compared to a target value. The target value may be so chosen that it corresponds to a designed triggering frequency of the switching circuit 26. If the counting signal 34 is lower than the target value, it may be an indication that the triggering pulses at the switching circuit 26 occur too frequently. In order to remedy the situation, the hysteresis level adjuster 42 may generate a positive delta voltage V_delta 44 to raise the reference voltage V_ref 20 and consequently the hysteresis limits. This effectively biases the comparator 18 to skip a trigger event. Inversely, when the counting signal 34 is higher than the target value, it may be indicating that the triggering pulses occur too infrequently. In order to force a trigger, the hysteresis level adjuster 42 may generate a negative delta voltage V_delta 44 to lower the reference voltage V_ref 20 and consequently the hysteresis limits.

The delta voltage V_delta 44, positive or negative, is applied to the reference voltage V_ref 20 at the hysteresis level adder 46. The combination of the reference voltage and the delta voltage is then applied as the adjusted reference voltage to the comparator 18 to affect the modulation of the switching action.

In this embodiment, the switching circuit, which contains one or more power switches in the form of power MOSFETs, may or may not be integrally built on the same semiconductor chip. If the power switches are integrated with the pulse width modulator and the rest of the switching circuit, the chip may be referred to as a single chip power regulator. If, on the other hand, the switches and the controller are built on separate semiconductor chips, the chips can still be assembled in an integral package and function as a full power regulator.

The combination of a digital counter and a high-speed clock can provide very high resolution to the count signal. Some applications, however, do not require such degree of resolution. If the controller does not otherwise need a high-speed clock, the shifting of the hysteresis of the comparator may be accomplished with simpler passive timer circuits. One exemplary implementation would be a capacitor circuit in which the charging or the discharging the capacitor is tuned to a fixed time close to one cycle or a fractional cycle of the desired switching pulses.

We claim:

1. A power controller, comprising:
a comparator circuit that compares a reference signal to an analog signal derived from an output siganl, and outputs a one-bit binary signal based on the comparison; and
a counter circuit that receives the single-bit binary signal from the comparator circuit and generates a signal proportional to the duration of the binary signal when it stays in one of the two binary states.

2. The power controller of claim 1, in which the counter circuit interrogates the single-bit binary signal at a first frequency.

3. The power controller of claim 2, further comprising a pulse width modulator.

4. The power controller of claim 3, in which the pulse width modulator outputs a pulse signal having a switching frequency lower than the first frequency.

5. The power controller of claim 4, in which the first frequency is not less than 64 times the switching frequency.

6. The power controller of claim 4, in which the first frequency is not less than 100 times the switching frequency.

7. The power controller of claim 4, in which the first frequency is not less than a thousand times the switching frequency.

8. The power controller of claim 1, in which the analog signal is a voltage signal and is fraction of the output signal.

9. A voltage regulator, comprising:
a comparator circuit that compares a reference signal to an analog signal derived from an output siganl, and outputs a one-bit binary signal based on the comparison; and
a clock circuit generating a clock signal at a clock frequency;
a counter circuit that receives the single-bit binary signal from the comparator circuit and interrogates the single-bit binary signal at the clock frequency and generates a counting signal proportional to the duration of the binary signal when it stays in one of the two binary states;
a delta generator circuit comparing the counting signal to a target value and generating a delta signal; and
a pulse width modulator receiving the delta signal and generating a pulse signal having a switching frequency.

10. The voltage regulator of claim 9, in which the switching frequency is lower than the clock frequency.

11. The voltage regulator of claim 9, further comprising a look-up table circuit, which receives the delta signal and generates a look-up signal.

12. The voltage regulator of claim 11, in which the look-up signal is fed to the pulse width modulator.

13. The voltage regulator of claim 12, in which the look-up signal is selected from a set of pre-determined numbers selectably arranged in the look-up table.

14. The voltage regulator of claim 12, in which the look-up signal is generated from a formula using the delta signal as an input parameter.

15. The voltage regulator of claim 14, in which the formula comprises a linear equation of the delta signal.

16. The voltage regulator of claim 14, in which the formula is a non-linear equation of the delta signal.

17. A voltage regulator comprising:
a comparator circuit that compares a reference signal to an analog signal derived from an output signal, and outputs a one-bit binary signal based on the comparison; and
a hysteresis level adjuster for generating a delta signal, based on the one-bit binary signal, for modifying the reference signal.

18. The voltage regulator of claim 17, in which the reference signal is represented in the comparator by a high voltage limit and a low voltage limit.

19. The voltage regulator of claim 17, further comprising a hysteresis level adder for combining the reference voltage and the delta signal.

20. The voltage regulator of claim 19, in which the combined reference signal and the delta signal is fed to a first input terminal of the comparator.

21. The voltage regulator of claim 20, in which the high voltage limit and the low voltage limit are adjustable set according to the combined reference voltage and the delta signal.

22. The voltage regulator of claim 19, further comprising a digital counter that interrogates the one-bit binary signal at a speed of a clock and generates a counting signal.

23. The voltage regulator of claim 22, in which the counting signal is fed to the hysteresis level adjuster for computing for the delta signal.

24. The voltage regulator of claim 19 further comprises a semiconductor chip without a power MOSFET on the semiconductor chip.

25. The voltage regulator of claim 19 further comprises a semiconductor chip including a power MOSFET on the semiconductor chip.
